(19) United States
(12) Patent Application Publication
(10) Pub. No.: US 2026/0133704 A1
(43) Pub. Date: May 14, 2026

(54) ENABLING LOGICAL OPERATIONS IN LOW-POWER, DOUBLE DATA RATE (LPDDR) MEMORY

(71) Applicant: QUALCOMM Incorporated, San Diego, CA (US)

(72) Inventors: Sang TRAN, Encinitas, CA (US); Rongtian ZHANG, San Diego, CA (US)

(21) Appl. No.: 18/948,279

(22) Filed: Nov. 14, 2024

(51) Int. Cl. G06F 3/06

(52) U.S. Cl. CPC G06F 3/0625; G06F 3/0659; G06F 3/0673

(57) ABSTRACT

A memory apparatus includes two independent subchannels of double data rate (DDR) memory. Each subchannel includes a number of memory banks, and an input/output (I/O) block having a number of meta data registers. The memory apparatus also includes a processing unit. The processing unit includes an arithmetic logic unit (ALU), an accumulator coupled to an output of the ALU, a controller coupled to the ALU, two multiplexers, each multiplexer coupling one subchannel to an ALU input, and coupling the accumulator to the ALU input, and two multiplexers/demultiplexers. Each multiplexer/demultiplexer is coupled between a memory bank, a corresponding I/O block, one of the two multiplexers, and the accumulator.

### FIELD OF THE DISCLOSURE

Aspects of the present disclosure generally relate to memory systems, and more particularly to enabling logical operations in low-power, double data rate (LPDDR) memory.

### BACKGROUND

In computing systems, memory may be volatile memory or non-volatile memory. Volatile memory, such as random access memory (RAM), specifies continuous power to maintain stored data. Volatile memory is primarily used for temporary storage while a processor is performing computations. Non-volatile memory, such as negative OR (NOR) memory and negative AND (NAND) memory used in solid state drives (SSDs) and hard drives, retains data even when powered off, making non-volatile memory preferable for long-term data storage.

A host device, such as a system-on-a-chip (SoC), may be coupled to memory via command buses, data buses, and clock buses. Command buses transmit operational instructions from the SoC to memory. The SoC may use a command bus to direct how data should be handled, whether stored, erased, or modified. Data buses facilitate the transfer of data back and forth between the SoC and the memory, enabling the system to access and utilize the data as specified for processing tasks. Clock buses provide timing signals to synchronize data transfers and operations across the system.

Unfortunately, communications between the host device and the memory are slower than on-chip communications. Moreover, bandwidth restrictions may further limit the communications between the host and the memory. It would be desirable to improve processing involving memory, such as dynamic random access memory (DRAM), by reducing communications between the host and the memory.

### SUMMARY

Aspects of the present disclosure are directed to a memory apparatus. The apparatus includes two independent subchannels of double data rate (DDR) memory. Each subchannel includes a number of memory banks, and an input/output (I/O) block having a number of meta data registers. The apparatus also includes a processing unit including an arithmetic logic unit (ALU), an accumulator coupled to an output of the ALU, a controller coupled to the ALU, two multiplexers, each multiplexer coupling one subchannel to an ALU input, and coupling the accumulator to the ALU input, and two multiplexers/demultiplexers. Each multiplexer/demultiplexer is coupled between a memory bank, a corresponding I/O block, one of the two multiplexers, and the accumulator.

In other aspects of the present disclosure, a memory processing method includes selecting two inputs for an arithmetic logic unit (ALU). The two inputs are selected from a first independent subchannel of double data rate (DDR) memory, a second independent subchannel of DDR memory, an accumulator output, and/or internal static random access memory (SRAM). The method also includes performing vector operations on the two inputs with the ALU.

In still other aspects of the present disclosure, a non-transitory computer-readable medium with program code recorded thereon is disclosed. The program code is executed by a processor and includes program code to select two inputs for an arithmetic logic unit (ALU). The two inputs are selected from a first independent subchannel of double data rate (DDR) memory, a second independent subchannel of DDR memory, an accumulator output, and/or internal static random access memory (SRAM). The program code still further includes program code to perform vector operations on the two inputs with the ALU.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings in which like reference characters identify correspondingly throughout.

FIG. 1 illustrates an example implementation of a system-on-a-chip (SoC), in accordance with various aspects of the present disclosure.

FIG. 2 illustrates an SoC in conventional communication with memory, in accordance with various aspects of the present disclosure.

FIG. 3 illustrates negative OR (NOR) gate combinations for creating other logic gates.

FIG. 4 illustrates storing bits in a volatile memory, in accordance with various aspects of the present disclosure.

FIG. 5 illustrates a dynamic random access memory (DRAM) chip, in accordance with various aspects of the present disclosure.

FIG. 6 illustrates a state diagram, in accordance with various aspects of the present disclosure.

FIGS. 7A and 7B illustrate command truth tables, in accordance with various aspects of the present disclosure.

FIG. 8 illustrates a mode register assignment table, in accordance with various aspects of the present disclosure.

FIG. 9 illustrates a low-power, double data rate (LPDDR) memory architecture, in accordance with various aspects of the present disclosure.

FIG. 10 illustrates a processing in memory (PIM) LPDDR architecture, in accordance with various aspects of the present disclosure.

FIG. 11 illustrates various processing unit (PU) configurations for a PIM LPDDR architecture, in accordance with various aspects of the present disclosure.

FIG. 12 is a flow diagram illustrating an example process performed, for example, by a PIM device, in accordance with various aspects of the present disclosure.

FIG. 13 is a block diagram illustrating a design workstation used for circuit, layout, and logic design of components, in accordance with various aspects of the present disclosure.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

Based on the teachings, one skilled in the art should appreciate that the scope of the disclosure is intended to cover any aspect of the disclosure, whether implemented independently of or combined with any other aspect of the disclosure. For example, an apparatus may be implemented or a method may be practiced using any number of the aspects set forth. In addition, the scope of the disclosure is intended to cover such an apparatus or method practiced using other structure, functionality, or structure and functionality in addition to or other than the various aspects of the disclosure set forth. It should be understood that any aspect of the disclosure disclosed may be embodied by one or more elements of a claim.

The word “exemplary” is used to mean “serving as an example, instance, or illustration.” Any aspect described as “exemplary” is not necessarily to be construed as preferred or advantageous over other aspects.

Although particular aspects are described, many variations and permutations of these aspects fall within the scope of the disclosure. Although some benefits and advantages of the preferred aspects are mentioned, the scope of the disclosure is not intended to be limited to particular benefits, uses or objectives. Rather, aspects of the disclosure are intended to be broadly applicable to different technologies, system configurations, networks, and protocols, some of which are illustrated by way of example in the figures and in the following description of the preferred aspects. The detailed description and drawings are merely illustrative of the disclosure rather than limiting, the scope of the disclosure being defined by the appended claims and equivalents thereof.

Several aspects of data transfer techniques will now be presented with reference to various apparatuses and techniques. These apparatuses and techniques will be described in the following detailed description and illustrated in the accompanying drawings by various blocks, modules, components, circuits, steps, processes, algorithms, and/or the like (collectively referred to as “elements”). These elements may be implemented using hardware, software, or combinations thereof. Whether such elements are implemented as hardware or software depends upon the particular application and design constraints imposed on the overall system.

Data movement between a memory chip and a host, such as a central processing unit (CPU), is slower than on-chip communications. Bitwise operations completely inside a dynamic random access memory (DRAM) chip (e.g., double data rate (DDR) memory) may exploit the full internal DRAM bandwidth to reduce latency. By having the memory perform logic operations, data movement between the memory chip and the host is reduced. Such techniques may be referred to as processing in memory (PIM). These techniques may use a charge sharing phase to perform bulk bitwise AND and OR operations directly in DRAM. Performing bulk bitwise operations efficiently inside DRAM improves performance and reduces energy consumption compared to off-chip processing.

In other aspects, a processing unit (e.g., an arithmetic logic unit (ALU), controller, accumulator, and multiplexer) may be included in a DRAM chip to enable complex processing within the memory chip. Each of two independent subchannels of a DRAM is available as an input source for the ALU. An on-chip static random access memory (SRAM) is a third possible input source for the ALU. The ALU performs multiplication and addition operations on the inputs. For example, the ALU may perform vector operations or a single operation on the input. Results from the ALU operations may be stored in a subchannel bank of the DRAM or sent out to a host via an input/output (I/O) block.

Particular aspects of the subject matter described in this disclosure can be implemented to realize one or more of the following potential advantages. In some examples, the described techniques and components, such as performing complex operations within a double data rate (DDR) memory chip in the digital domain, reduces power consumption and latency compared with performing processing outside of the DDR memory chip.

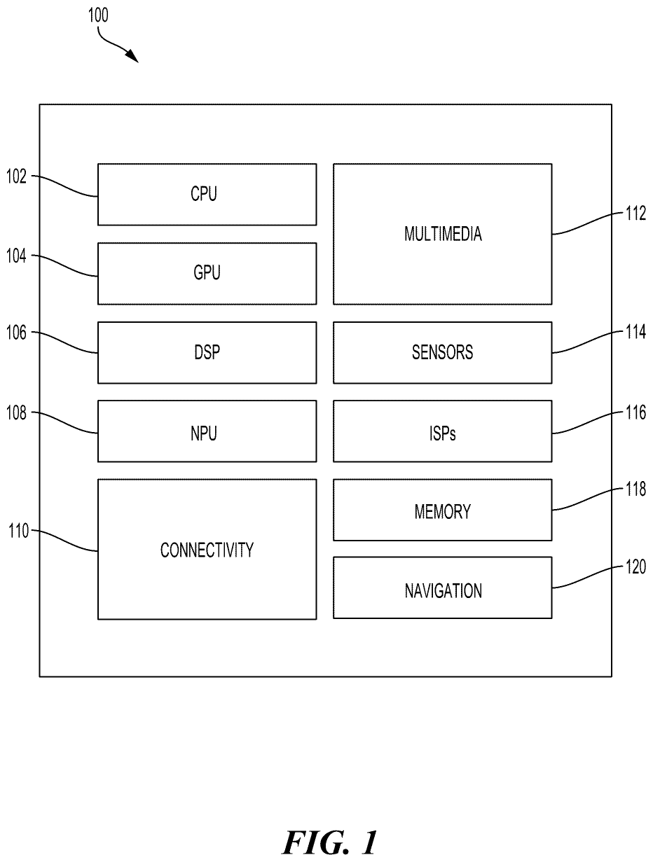

FIG. 1 illustrates an example implementation of a system-on-a-chip (SoC) 100, which may include a central processing unit (CPU) 102 or a multi-core CPU configured for memory operations. Variables (e.g., neural signals and synaptic weights), system parameters associated with a computational device (e.g., neural network with weights), delays, frequency bin information, and task information may be stored in a memory block associated with a neural processing unit (NPU) 108, in a memory block associated with a CPU 102, in a memory block associated with a graphics processing unit (GPU) 104, in a memory block associated with a digital signal processor (DSP) 106, in a memory block 118, or may be distributed across multiple blocks. Instructions executed at the CPU 102 may be loaded from a program memory associated with the CPU 102 or may be loaded from a memory block 118.

The SoC 100 may also include additional processing blocks tailored to specific functions, such as a GPU 104, a DSP 106, a connectivity block 110, which may include fifth generation (5G) connectivity, fourth generation long term evolution (4G LTE) connectivity, Wi-Fi connectivity, USB connectivity, Bluetooth connectivity, and the like, and a multimedia processor 112 that may, for example, detect and recognize gestures. In one implementation, the NPU 108 is implemented in the CPU 102, DSP 106, and/or GPU 104. The SoC 100 may also include a sensor processor 114, image signal processors (ISPs) 116, and/or navigation module 120, which may include a global positioning system.

The SoC 100 may be based on an ARM, RISC-V (RISC-five), or any reduced instruction set computing (RISC) architecture. In aspects of the present disclosure, the instructions loaded into the CPU 102 may include code to select two inputs for an arithmetic logic unit (ALU). The two inputs are selected from a first independent subchannel of double data rate (DDR) memory, a second independent subchannel of DDR memory, an accumulator output, and/or internal static random access memory (SRAM). In other aspects of the present disclosure, the instructions loaded into the CPU 102 may include code to perform vector operations on the two inputs with the ALU.

According to aspects of the present disclosure, an apparatus includes an SoC processor in memory (PIM) apparatus. The apparatus may include means for selecting and means for performing. For example, the means for selecting and means for performing may be any of the CPU 102, GPU 104, DSP 106, NPU 108, connectivity block 110, ISPs 116, memory block 118, controller 1016, ALU 1010, the multiplexer 1018, and/or the multiplexer/demultiplexer 1020.

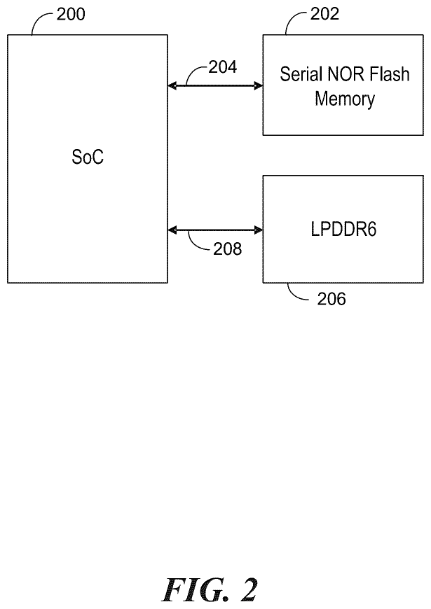

FIG. 2 illustrates an SoC in conventional communication with memory, in accordance with various aspects of the present disclosure. As shown in FIG. 2, an SoC 200 is coupled to serial negative OR (NOR) flash memory 202 via a first data bus 204. The SoC 200 is also coupled to low-power, double-data rate (LPDDR) memory 206 via a second data bus 208. The “6” appended to the “LPDDR” label in FIG. 2 indicates that the LPDDR memory 206 may be version six or later of LPDDR memory.

Aspects of the present disclosure propose an apparatus and method to enable operations in low-power, double data rate (LPDDR) memory. The OR, AND, and NOT are the three basic logic gates, as together they can construct a logic circuit for any given Boolean expression. NOR and negative AND (NAND) gates have the property that they individually can be used to hardware-implement any logic circuit. For this reason, the NAND and NOR gates are called universal gates.

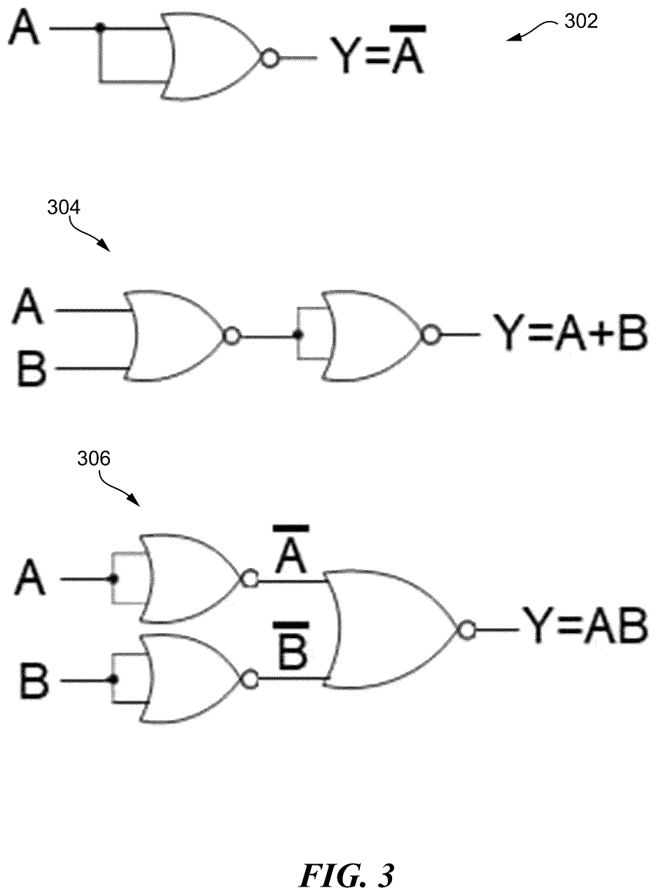

FIG. 3 illustrates NOR gate combinations for creating other logic gates. In a first combination 302, an input A passes through a NOR gate to perform an INVERSE (e.g., NOT) operation, such that the output Y is equal to the inverse of the input A. In second and third combinations 304, 306, inputs A and B traverse a combination of NOR gates to perform an OR operation (304), and inputs A and B traverse a combination of NOR gates to perform an AND operation (306).

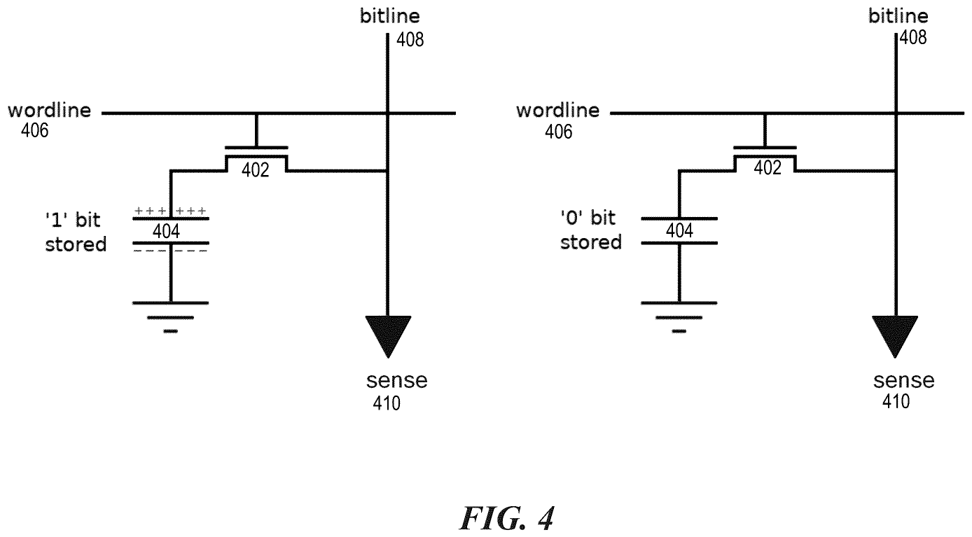

FIG. 4 illustrates storing bits in a volatile memory, in accordance with various aspects of the present disclosure. When storing a bit in memory, a transistor 402 charges or discharges a capacitor 404. A charged capacitor represents a logic high or ‘1’ while a discharged capacitor represents a logic low or “0.’ The charging or discharging is performed via a wordline 406 and a bitline 408.

For reading and writing the value in the bit, the wordline 406 goes high and the transistor 402 connects the capacitor 404 to the bitline 408. The value on the bitline 408 (‘1’ or ‘0’) is stored or retrieved from the capacitor 404. Charge stored on each capacitor 404 is too small to be read directly and is instead measured by a circuit called a sense amplifier 410. The sense amplifier 410 detects minute differences in charge and outputs a corresponding logic level. The act of reading from the bitline 408 forces the charge to flow out of the capacitor 404. The read process in dynamic random access memory (DRAM) is destructive and removes the charge on the memory cells in an entire row. Thus, there is a column of specialized latches on the chip called sense amplifiers, one for each column of memory cells, to temporarily hold the data. During a normal read operation, the sense amplifiers after reading and latching the data, rewrite the data in the accessed row. Because capacitors 404 leak charge over time, capacitors 404 are refreshed periodically to maintain the data stored in memory. Refreshing operates like a read and ensures data is never lost.

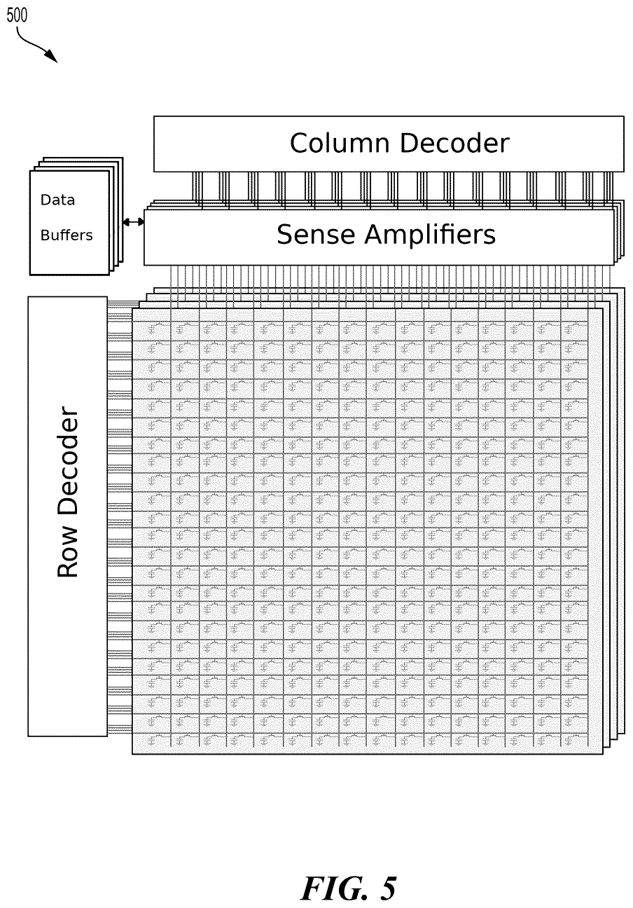

FIG. 5 illustrates a dynamic random access memory (DRAM) chip 500, in accordance with various aspects of the present disclosure. DRAM chips are organized into a number of banks that contain a set of memory arrays. FIG. 5 shows a single x4 bank of the DRAM chip 500. A memory array is designed as a grid of rows and columns. Decoders access the rows and columns, selecting a single intersection within the memory array. A capacitor (e.g., the capacitor 404) stores a charge representing the data being accessed at the intersection. Sense amplifiers perform pre-charge operations on capacitors and store logic-level outputs in data buffers until the data can be retrieved by a memory controller or central processing unit (CPU).

The analog operation of DRAM technology may be exploited to perform bitwise operations completely inside the DRAM chip, thereby exploiting the full internal DRAM bandwidth. By having the memory perform logic operations, movement between the memory and the CPU is reduced. Such techniques may be referred to as processing in memory (PIM). These techniques use the charge sharing phase to perform bulk bitwise AND and OR operations directly in DRAM. The bitwise majority expression C(A+B)+C′(AB) may be performed by charge sharing. Performing a bulk bitwise NOT operation in DRAM transfers the data on the bitline to a cell that can also be connected to a bitline bar. Thus, any bulk bitwise operation may be performed efficiently inside DRAM, significantly improving performance and reducing energy consumption compared to state of the art systems.

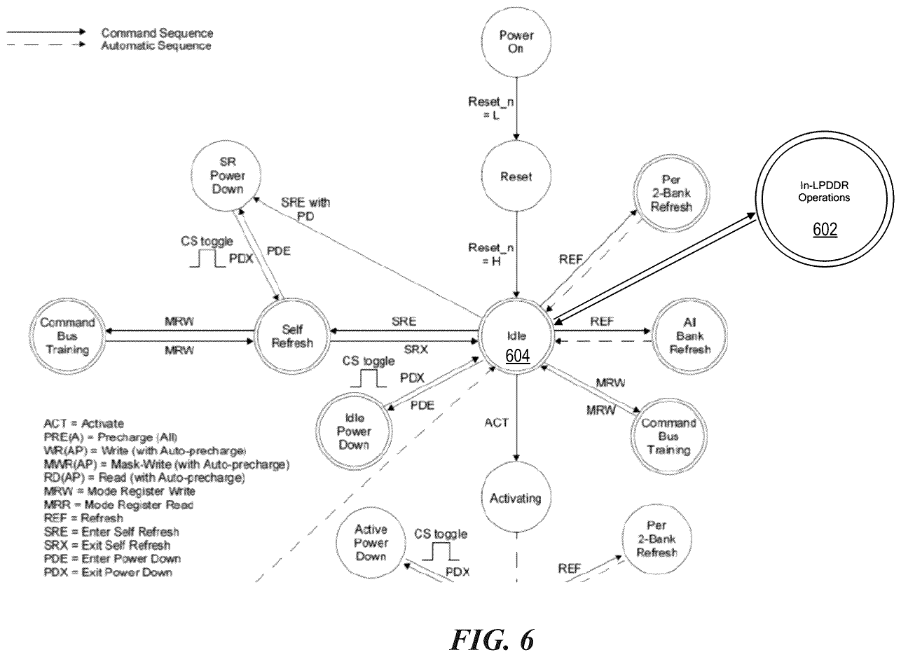

Aspects of the present disclosure introduce techniques to enable LPDDR memory to perform bitwise operations. FIG. 6 illustrates a state diagram, in accordance with various aspects of the present disclosure. As seen in the example of FIG. 6, the in-LPDDR memory operations may be a new state 602 of available LPDDR memory states to be entered by an LPDDR chip, in addition to existing LPDDR memory states. The new state 602 supports the proposed PIM instructions. In some implementations, the LPDDR memory transitions from Idle State 604 to an In-LPDDR Operations State 602 when the memory is commanded to carry out PIM related operations. The LPDDR memory could also transition to the In-LPDDR Operations State 602 from states other than the Idle State 604.

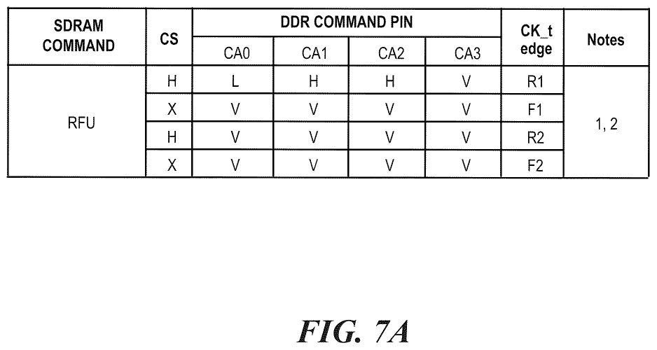

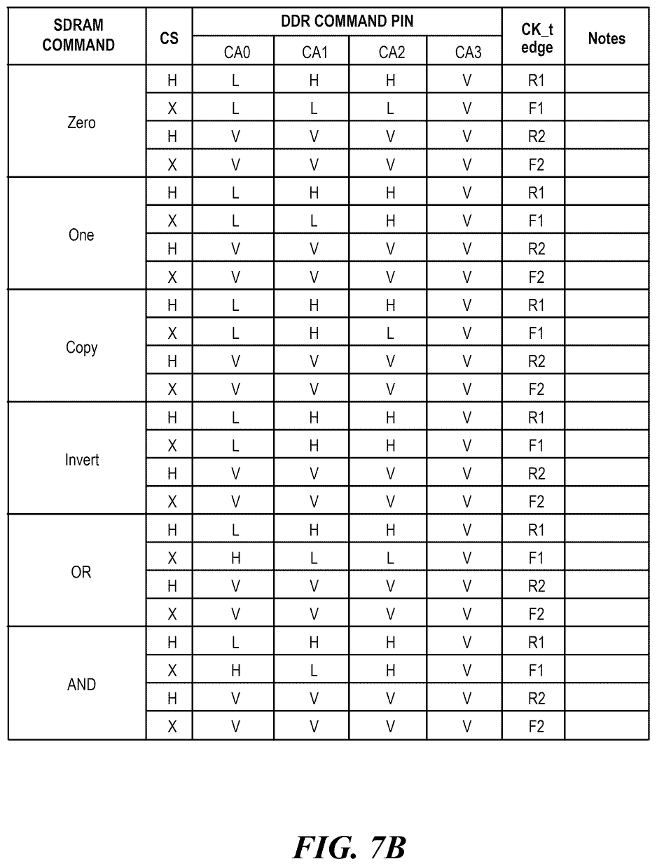

FIGS. 7A and 7B illustrate command truth tables, in accordance with various aspects of the present disclosure. According to aspects of the present disclosure, commands currently reserved for future use (RFU) may be assigned basic operations, for example: Zero (all values in a row become zeros), One (all values in a row become ones), Copy, Invert, OR, and AND. FIG. 7A illustrates one possible assignment. The unassigned values “V” (or don't care) can convey a bank and bank group address. Signals between the application processor and the memory (e.g., DDR command pins) on command address buses (CA0 to CA3) may be set to low (L) or high (H). The chip select line (CS) is part of the command code. The clock true (CK_t) edge value may be indicated as rising on a first or second clock cycle (R1 and R2, respectively) or falling on a first or second clock cycle (F1 and F2, respectively). In case a clock is a differential signal, such value may be complementary, rather than absolute. As seen in FIG. 7B, the column addresses are not included because each command operates on an entire row.

As shown in FIG. 7B, in some aspects, the host may decompose more complex commands (e.g., add, subtract, multiplication) into basic logic operation, such as Zero, One, Copy, Invert, OR, and AND, before sending the commands to the memory device. Therefore, the host may offload work to the memory device. Alternatively, the memory device may support more complex commands. When the memory device receives a complex command from the host, the memory device decomposes the complex command into basic logic operations before executing the complex command.

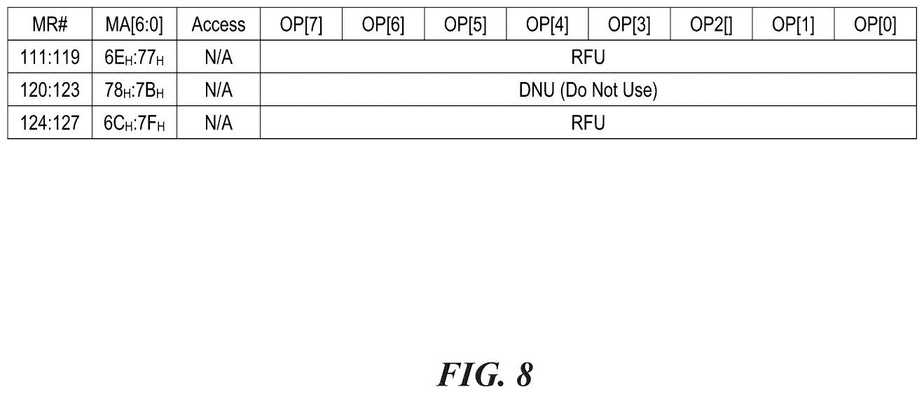

FIG. 8 illustrates a mode register assignment table, in accordance with various aspects of the present disclosure. Current reserved for future use (RFU) registers may store row addresses for Zero, One, IN1 (input one), IN2 (input 2), and OUT (output). The RFU registers may also include a temporary region for storing intermediate results or parameters. Two mode registers provide 16 bits to store up to 2¹⁶ row addresses. In the example of FIG. 8, the mode register (MR) numbers are indicated in decimal notation, whereas the mode addresses (MA) are indicated in hexadecimal notation. Each mode register operand (OP[0] to OP[7]) may store eight bits.

Any complex logical operation can be decomposed into AND, OR, and INVERT operations. The following example illustrates how a bitwise exclusive OR (XOR) operation is performed. The algebraic expression for an XOR gate is X=AB′+A′B.

First, the IN1 mode registers are programmed to store the row address of input A (simply referred to as ‘A’), and then the content of the row A address is copied to the first location of the temporary region. Next, the IN2 mode registers are programmed to store the row address of input B (referred to as ‘B’), and the content of the row B address is copied to the second location of the temporary region.

The memory performs an INVERT operation on the temporary region second location, and then performs a Zero operation on the temporary region third location. The memory performs an AND operation to obtain AB′ intermediate result and copies the AB′ intermediate result to a designated row address. These steps then repeat with A interchanged with B to obtain A′B.

These steps repeat again with A replaced by AB′ and with B replaced by A′B. However, during this latter repetition, the Zero operation changes to a One operation, and the AND operation changes to an OR operation. The final XOR result may be copied into the row specified in the OUT mode register.

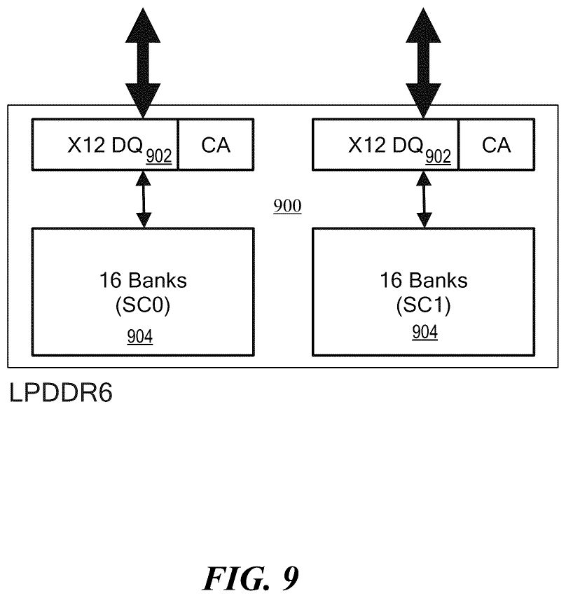

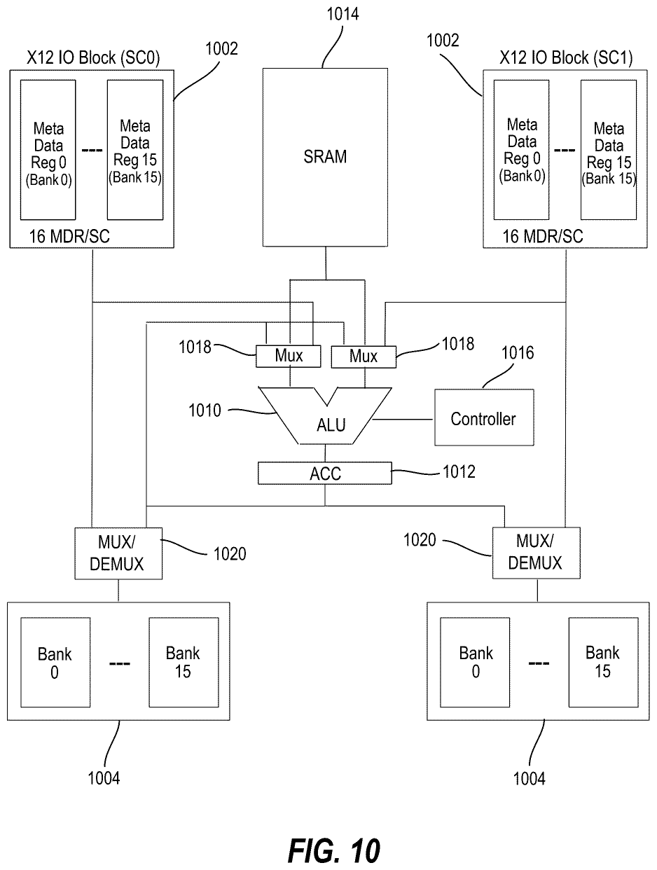

FIG. 9 illustrates an LPDDR memory architecture, in accordance with various aspects of the present disclosure. In the example of FIG. 9, two independent subchannels (SC0 and SC1) are shown. Each subchannel of LPDDR memory 900 includes an input/output (I/O) block 902 and memory banks 904 (two sixteen memory banks 904 in the example of FIG. 9.) In the example of FIG. 9, each subchannel I/O block 902 has 12 data lines (DQs) and a command address bus (CA). Each subchannel I/O block 902 also includes sixteen meta data registers (MDR0-MDR15, see FIG. 10). Each meta data register is 32-bytes wide.

FIG. 10 illustrates a processing in memory (PIM) LPDDR architecture, in accordance with various aspects of the present disclosure. In the example of FIG. 10, an arithmetic logic unit (ALU) 1010, and an ALU accumulator (ACC) 1012 are provided in addition to subchannel memory banks 1004 and I/O blocks 1002, which are similar to the elements of FIG. 9. An optional internal static random access memory (SRAM) 1014, a controller 1016, multiplexers 1018, and multiplexers/demultiplexers (MUX/DEMUX) 1020 are also provided. The accumulator 1012 permits repeated operations, for example, with artificial intelligence or machine learning processing. For example, output from the ALU 1010 may be stored in the accumulator 1012 and that output may be multiplied with a previous result, etc., until a final result is achieved. By adding a processing unit (e.g., the ALU 1010, controller 1016, accumulator 1012, multiplexers 1018, and MUX/DEMUXes 1020), complex processing within the DDR memory is achievable.

The line connecting the I/O block 1002 and MUX/DEMUX 1020 is now described. The multiplexors 1018 provide input to the ALU 1010 from this line, the accumulator 1012, or the SRAM 1014. The MUX/DEMUX 1020 operates bidirectionally. When the MUX/DEMUX 1020 function as a multiplexor, the MUX/DEMUX 1020 can select either the I/O block 1002 or the ACC 1012 as input to the subchannel memory banks 1004 (e.g., writing to the subchannel memory banks 1004). For demultiplexing functionality, the MUX/DEMUX 1020 provide outputs from the subchannel memory banks 1004, so that the multiplexor 1018 may select input to the ALU 1010 from any output from the MUX/DEMUX 1020. The left output from the MUX/DEMUX 1020 provides a path (e.g., reading) to the I/O block 1002.

Each of the two independent subchannels is available as an input source for the ALU 1010. More specifically, each multiplexer 1018 enables the ALU 1010 to receive input from the corresponding I/O block 1002 (e.g., from the host or the meta data register), any bank of the corresponding subchannel memory bank 1004, or results from the accumulator 1012 output. Thus, two inputs may be received from the independent subchannel memory banks 1004. The SRAM 1014 is a third possible input source for the ALU 1010, via the multiplexers 1018. The host loads the data into the SRAM 1014 through subchannel zero (SC0) and/or subchannel one (SC1). Although not shown in FIG. 10, it is also possible for the accumulator 1012 to save the results into the SRAM 1014.

In some implementations, the ALU 1010 performs multiply and add operations on inputs. For example, the ALU 1010 may perform vector operations such as single instruction multiple data (SIMD) operations in parallel (e.g., 16 multipliers operating on 16 bits) or may perform a single operation on a wide data input (e.g., multiply by 256 bits). Results from the ALU operations may be stored in a subchannel memory bank 1004 or sent out to the host via the I/O block 1002.

The controller 1016 may include an instruction sequencer. In-LPDDR memory instructions can originate from a host command, a mode register inside the controller (e.g., the mode register of FIG. 8), or the instruction sequencer. The host downloads a command or instruction to the controller 1016 through subchannel zero (SC0) and/or subchannel one (SC1), and the host command or instruction is then stored in the controller 1016. The controller 1016 executes a sequence of instructions, for example, similar to an XOR gate. Based on the instructions, the controller 1016 controls which inputs the ALU 1010 should receive. For example, input A may be a row of data from bank 0 of subchannel 0, and input B may come from the accumulator 1012. If the input data originates from the I/O block 1002, the input data may originate from one of the large meta data registers in the I/O block 1002 that store the input A or input B.

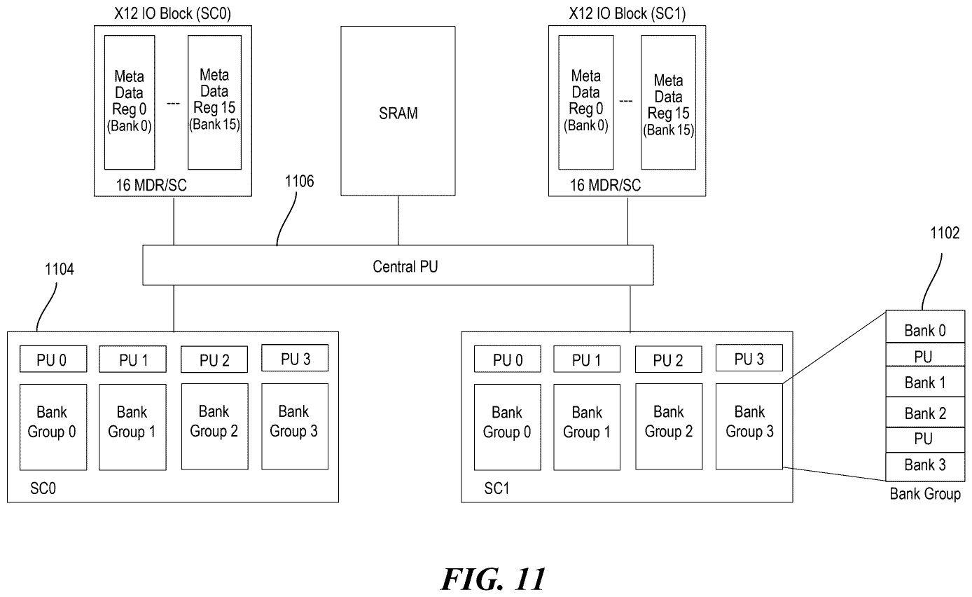

By adding the processing unit (e.g., the ALU 1010, controller 1016, accumulator 1012, and multiplexors 1018, 1020), processing within the DDR memory apparatus becomes possible. FIG. 11 illustrates various processing unit (PU) configurations for a PIM LPDDR architecture, in accordance with various aspects of the present disclosure. For example, one PU may be provided for every two banks, as seen in a first configuration 1102. In a second configuration 1104, one PU may be provided for each bank group, where four banks may comprise a bank group. In a third configuration 1106, a top level PU is provided between two subchannels. That is, a single central PU is provided for all banks of the DRAM (e.g., as shown in FIG. 10). The different configurations 1102, 1104, 1106 may be mutually exclusive or may occur in any combination, and may be configured statically or dynamically by the host. The host may enable a specific configuration based on per instruction or group of instructions depending on the power or performance requirements. For example, a central PU and a PU for each memory bank may be provided in one architecture. By providing more PUs, processing becomes quicker within the DRAM.

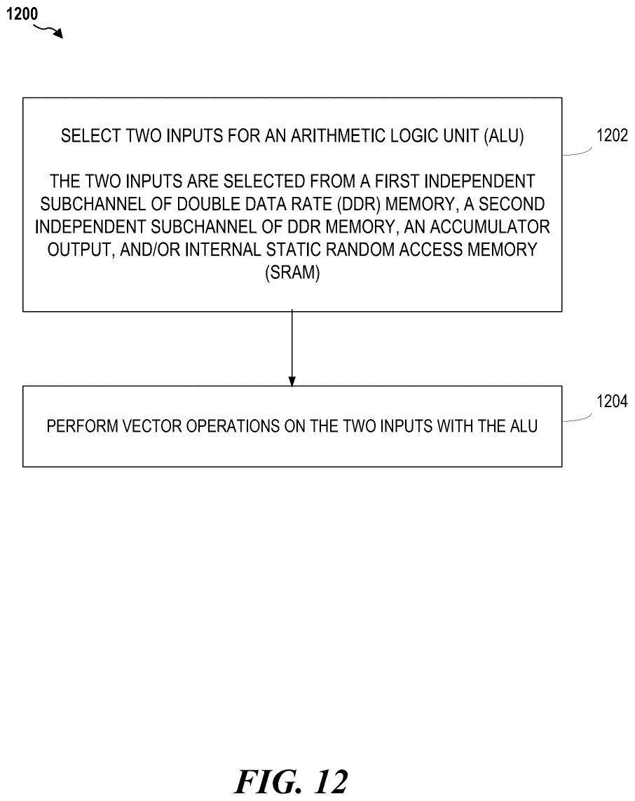

FIG. 12 is a flow diagram illustrating an example process performed, for example, by a processing in memory (PIM) device, in accordance with various aspects of the present disclosure. The process 1200 may be performed by one or more processors such as the CPU 102, GPU 104 and/or another processing unit.

As shown in FIG. 12, in some aspects, the process 1200 may include selecting two inputs for an arithmetic logic unit (ALU). The two inputs are selected from a first independent subchannel of double data rate (DDR) memory, a second independent subchannel of DDR memory, an accumulator output, and/or internal static random access memory (SRAM) (Block 1202). The first independent subchannel of DDR memory may include a first set of meta data registers and a first set of memory banks and the second independent subchannel of DDR memory may include a second set of meta data registers and a second set of memory banks.

In some aspects, the process 1200 may also include performing vector operations on the two inputs with the ALU (Block 1204). The vector operations may be a single instruction multiple data (SIMD) operation or a single operation.

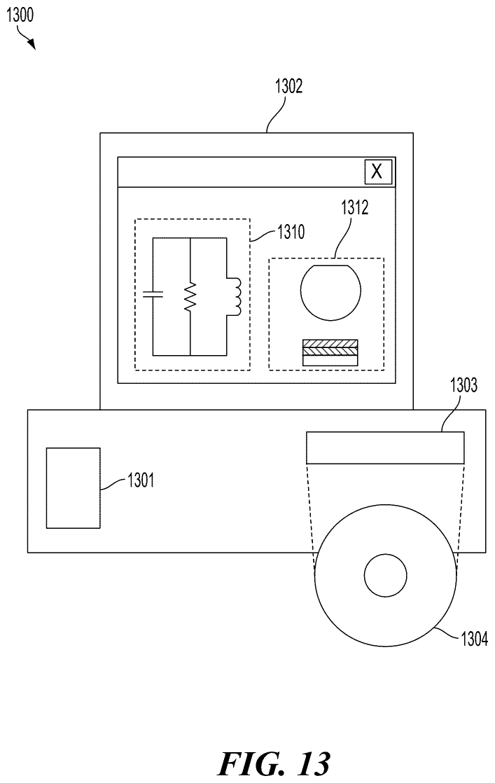

FIG. 13 is a block diagram illustrating a design workstation 1300 used for circuit, layout, and logic design of a semiconductor component, such as the PIM architecture, disclosed above. The design workstation 1300 includes a hard disk 1301 containing operating system software, support files, and design software such as Cadence or OrCAD. The design workstation 1300 also includes a display 1302 to facilitate design of a circuit 1310 or a semiconductor component 1212, such as the mode registers. A storage medium 1304 is provided for tangibly storing the design of the circuit 1310 or the semiconductor component 1312 (e.g., the PIM architecture). The design of the circuit 1310 or the semiconductor component 1312 may be stored on the storage medium 1304 in a file format such as GDSII or GERBER. The storage medium 1304 may be a CD-ROM, DVD, hard disk, flash memory, or other appropriate device. Furthermore, the design workstation 1300 includes a drive apparatus 1303 for accepting input from or writing output to the storage medium 1304.

Data recorded on the storage medium 1304 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1304 facilitates the design of the circuit 1310 or the semiconductor component 1312 by decreasing the number of processes for designing semiconductor wafers.

### Example Aspects

Aspect 1: A memory apparatus, comprising: two independent subchannels of double data rate (DDR) memory, each subchannel comprising a plurality of memory banks, and an input/output (I/O) block having a plurality of meta data registers; and a processing unit comprising an arithmetic logic unit (ALU), an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

Aspect 2: The memory apparatus of Aspect 1, further comprising an internal static random access memory (SRAM) selectively coupled to the ALU input via the two multiplexers.

Aspect 3: The memory apparatus of Aspect 1 or 2, in which the ALU is configured to receive two inputs from the two independent subchannels, the accumulator, and/or the internal SRAM, and perform vector operations on the two inputs.

Aspect 4: The memory apparatus of any of the preceding Aspects, in which the controller is configured to select sources for the two inputs.

Aspect 5: The memory apparatus of any of the preceding Aspects, in which the processing unit comprises a central processing unit between the two independent subchannels.

Aspect 6: The memory apparatus of any of the Aspects 1-4, in which the processing unit comprises a plurality of processing units, with one processing unit assigned to each bank group.

Aspect 7: The memory apparatus of any of the preceding Aspects, in which each bank group comprises four memory banks.

Aspect 8: The memory apparatus of any of the Aspects 1-4, in which the processing unit comprises a plurality of processing units, with one processing unit assigned to every two memory banks.

Aspect 9: A memory processing method, comprising: selecting two inputs for an arithmetic logic unit (ALU), the two inputs selected from a first independent subchannel of double data rate (DDR) memory, a second independent subchannel of DDR memory, an accumulator output, and/or internal static random access memory (SRAM); and performing vector operations on the two inputs with the ALU.

Aspect 10: The method of Aspect 9, in which the first independent subchannel of DDR memory comprises a first plurality of meta data registers and a first plurality of memory banks and the second independent subchannel of DDR memory comprises a second plurality of meta data registers and a second plurality of memory banks.

Aspect 11: The method of Aspect 9 or 10, further comprising storing output of the vector operations in the first plurality of meta data registers, the first plurality of memory banks, the second plurality of meta data registers, and/or the second plurality of memory banks.

Aspect 12: The method of any of the Aspects 9-11, in which the vector operations comprise a single instruction multiple data (SIMD) operation or a single operation.

Aspect 13: The method of any of the Aspects 9-12, further comprising performing the vector operations from memory instructions received as a host command, received from a mode register within a controller, or received from an instruction sequencer within the controller.

Aspect 14: The method of any of the Aspects 9-13, further comprising configuring a processing unit as a central processing unit between two independent subchannels, the processing unit comprising an arithmetic logic unit (ALU), an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

Aspect 15: The method of any of the Aspects 9-13, further comprising configuring a plurality of processing units, with one processing unit assigned to each bank group, each processing unit comprising an arithmetic logic unit (ALU), an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

Aspect 16: The method of any of the Aspects 9-13, further comprising configuring a plurality of processing units, with one processing unit assigned to every two memory banks, each processing unit comprising an arithmetic logic unit (ALU), an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

Aspect 17: The method of any of the Aspects 9-16, further comprising transitioning from an idle state to an In-LPDDR (low-power DDR) operations state in response to receiving instructions for processing in memory (PIM) operations.

Aspect 18: A non-transitory computer-readable medium having program code recorded thereon, the program code executed by a processor and comprising: program code to select two inputs for an arithmetic logic unit (ALU), the two inputs selected from a first independent subchannel of double data rate (DDR) memory, a second independent subchannel of DDR memory, an accumulator output, and/or internal static random access memory (SRAM); and program code to perform vector operations on the two inputs with the ALU.

Aspect 19: The non-transitory computer-readable medium of Aspect 18, in which the first independent subchannel of DDR memory comprises a first plurality of meta data registers and a first plurality of memory banks and the second independent subchannel of DDR memory comprises a second plurality of meta data registers and a second plurality of memory banks.

Aspect 20: The non-transitory computer-readable medium of Aspect 18 or 19, in which the program code comprises program code to store output of the vector operations in the first plurality of meta data registers, the first plurality of memory banks, the second plurality of meta data registers, and/or the second plurality of memory banks.

The various operations of methods described above may be performed by any suitable means capable of performing the corresponding functions. The means may include various hardware and/or software component(s) and/or module(s), including, but not limited to, a circuit, an application specific integrated circuit (ASIC), or processor. Generally, where there are operations illustrated in the figures, those operations may have corresponding counterpart means-plus-function components with similar numbering.

As used, the term “determining” encompasses a wide variety of actions. For example, “determining” may include calculating, computing, processing, deriving, investigating, looking up (e.g., looking up in a table, a database, or another data structure), ascertaining and the like. Additionally, “determining” may include receiving (e.g., receiving information), accessing (e.g., accessing data in a memory) and the like. Furthermore, “determining” may include resolving, selecting, choosing, establishing, and the like.

As used, a phrase referring to “at least one of” a list of items refers to any combination of those items, including single members. As an example, “at least one of: a, b, or c” is intended to cover: a, b, c, a-b, a-c, b-c, and a-b-c.

The various illustrative logical blocks, modules and circuits described in connection with the present disclosure may be implemented or performed with a general-purpose processor, a digital signal processor (DSP), an application specific integrated circuit (ASIC), a field programmable gate array signal (FPGA) or other programmable logic device (PLD), discrete gate or transistor logic, discrete hardware components or any combination thereof designed to perform the functions described. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in any form of storage medium that is known in the art. Some examples of storage media that may be used include random access memory (RAM), read only memory (ROM), flash memory, erasable programmable read-only memory (EPROM), electrically erasable programmable read-only memory (EEPROM), registers, a hard disk, a removable disk, a CD-ROM and so forth. A software module may comprise a single instruction, or many instructions, and may be distributed over several different code segments, among different programs, and across multiple storage media. A storage medium may be coupled to a processor such that the processor can read information from, and write information to, the storage medium. In the alternative, the storage medium may be integral to the processor.

The methods disclosed comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a device. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement signal processing functions. For certain aspects, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processor may be responsible for managing the bus and general processing, including the execution of software stored on the machine-readable media. The processor may be implemented with one or more general-purpose and/or special-purpose processors. Examples include microprocessors, microcontrollers, DSP processors, and other circuitry that can execute software. Software shall be construed broadly to mean instructions, data, or any combination thereof, whether referred to as software, firmware, middleware, microcode, hardware description language, or otherwise. Machine-readable media may include, by way of example, random access memory (RAM), flash memory, read only memory (ROM), programmable read-only memory (PROM), erasable programmable read-only memory (EPROM), electrically erasable programmable Read-only memory (EEPROM), registers, magnetic disks, optical disks, hard drives, or any other suitable storage medium, or any combination thereof. The machine-readable media may be embodied in a computer-program product. The computer-program product may comprise packaging materials.

In a hardware implementation, the machine-readable media may be part of the processing system separate from the processor. However, as those skilled in the art will readily appreciate, the machine-readable media, or any portion thereof, may be external to the processing system. By way of example, the machine-readable media may include a transmission line, a carrier wave modulated by data, and/or a computer product separate from the device, all which may be accessed by the processor through the bus interface. Alternatively, or in addition, the machine-readable media, or any portion thereof, may be integrated into the processor, such as the case may be with cache and/or general register files. Although the various components discussed may be described as having a specific location, such as a local component, they may also be configured in various ways, such as certain components being configured as part of a distributed computing system.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may comprise one or more neuromorphic processors for implementing the neuron models and models of neural systems described. As another alternative, the processing system may be implemented with an application specific integrated circuit (ASIC) with the processor, the bus interface, the user interface, supporting circuitry, and at least a portion of the machine-readable media integrated into a single chip, or with one or more field programmable gate arrays (FPGAs), programmable logic devices (PLDs), controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

The machine-readable media may comprise a number of software modules. The software modules include instructions that, when executed by the processor, cause the processing system to perform various functions. The software modules may include a transmission module and a receiving module. Each software module may reside in a single storage device or be distributed across multiple storage devices. By way of example, a software module may be loaded into RAM from a hard drive when a triggering event occurs. During execution of the software module, the processor may load some of the instructions into cache to increase access speed. One or more cache lines may then be loaded into a general register file for execution by the processor. When referring to the functionality of a software module below, it will be understood that such functionality is implemented by the processor when executing instructions from that software module. Furthermore, it should be appreciated that aspects of the present disclosure result in improvements to the functioning of the processor, computer, machine, or other system implementing such aspects.

If implemented in software, the functions may be stored or transmitted over as one or more instructions or code on a computer-readable medium. Computer-readable media include both computer storage media and communication media including any medium that facilitates transfer of a computer program from one place to another. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Additionally, any connection is properly termed a computer-readable medium. For example, if the software is transmitted from a website, server, or other remote source using a coaxial cable, fiber optic cable, twisted pair, digital subscriber line (DSL), or wireless technologies such as infrared (IR), radio, and microwave, then the coaxial cable, fiber optic cable, twisted pair, DSL, or wireless technologies such as infrared, radio, and microwave are included in the definition of medium. Disk and disc, as used, include compact disc (CD), laser disc, optical disc, digital versatile disc (DVD), floppy disk, and Blu-ray® disc where disks usually reproduce data magnetically, while discs reproduce data optically with lasers. Thus, in some aspects, computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media.

Thus, certain aspects may comprise a computer program product for performing the operations presented. For example, such a computer program product may comprise a computer-readable medium having instructions stored (and/or encoded) thereon, the instructions being executable by one or more processors to perform the operations described. For certain aspects, the computer program product may include packaging material.

Further, it should be appreciated that modules and/or other appropriate means for performing the methods and techniques described can be downloaded and/or otherwise obtained by a user terminal and/or base station as applicable. For example, such a device can be coupled to a server to facilitate the transfer of means for performing the methods described. Alternatively, various methods described can be provided via storage means (e.g., RAM, ROM, a physical storage medium such as a compact disc (CD) or floppy disk, etc.), such that a user terminal and/or base station can obtain the various methods upon coupling or providing the storage means to the device. Moreover, any other suitable technique for providing the methods and techniques described to a device can be utilized.

It is to be understood that the claims are not limited to the precise configuration and components illustrated above. Various modifications, changes, and variations may be made in the arrangement, operation, and details of the methods and apparatus described above without departing from the scope of the claims.

1. A memory apparatus, comprising:
two independent subchannels of double data rate (DDR) memory, each subchannel comprising a plurality of memory banks, and an input/output (I/O) block having a plurality of meta data registers; and
a processing unit comprising an arithmetic logic unit (ALU), an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

2. The memory apparatus of claim 1, further comprising an internal static random access memory (SRAM) selectively coupled to the ALU input via the two multiplexers.

3. The memory apparatus of claim 2, in which the ALU is configured to receive two inputs from the two independent subchannels, the accumulator, and/or the internal SRAM, and perform vector operations on the two inputs.

4. The memory apparatus of claim 3, in which the controller is configured to select sources for the two inputs.

5. The memory apparatus of claim 1, in which the processing unit comprises a central processing unit between the two independent subchannels.

6. The memory apparatus of claim 1, in which the processing unit comprises a plurality of processing units, with one processing unit assigned to each bank group.

7. The memory apparatus of claim 6, in which each bank group comprises four memory banks.

8. The memory apparatus of claim 1, in which the processing unit comprises a plurality of processing units, with one processing unit assigned to every two memory banks.

9. A memory processing method, comprising:
selecting two inputs for an arithmetic logic unit (ALU), the two inputs selected from a first independent subchannel of double data rate (DDR) memory, a second independent subchannel of the DDR memory, an accumulator output, and/or internal static random access memory (SRAM); and
performing vector operations on the two inputs with the ALU.

10. The method of claim 9, in which the first independent subchannel of DDR memory comprises a first plurality of meta data registers and a first plurality of memory banks and the second independent subchannel of the DDR memory comprises a second plurality of meta data registers and a second plurality of memory banks.

11. The method of claim 10, further comprising storing output of the vector operations in the first plurality of meta data registers, the first plurality of memory banks, the second plurality of meta data registers, and/or the second plurality of memory banks.

12. The method of claim 9, in which the vector operations comprise a single instruction multiple data (SIMD) operation or a single operation.

13. The method of claim 9, further comprising performing the vector operations from memory instructions received as a host command, received from a mode register within a controller, or received from an instruction sequencer within the controller.

14. The method of claim 9, further comprising configuring a processing unit as a central processing unit between two independent subchannels, the processing unit comprising the ALU, an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

15. The method of claim 9, further comprising configuring a plurality of processing units, with one processing unit assigned to each bank group, each processing unit comprising the ALU, an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

16. The method of claim 9, further comprising configuring a plurality of processing units, with one processing unit assigned to every two memory banks, each processing unit comprising the ALU, an accumulator coupled to an output of the ALU, a controller coupled to the ALU, two multiplexers, each multiplexer coupling one subchannel to an ALU input, and coupling the accumulator to the ALU input, and two multiplexers/demultiplexers, each multiplexer/demultiplexer coupled between a memory bank, a corresponding I/O block, one of the two multiplexers, and the accumulator.

17. The method of claim 9, further comprising transitioning from an idle state to an In-LPDDR (low-power DDR) operations state in response to receiving instructions for processing in memory (PIM) operations.

18. A non-transitory computer-readable medium having program code recorded thereon, the program code executed by a processor and comprising:
program code to select two inputs for an arithmetic logic unit (ALU), the two inputs selected from a first independent subchannel of double data rate (DDR) memory, a second independent subchannel of the DDR memory, an accumulator output, and/or internal static random access memory (SRAM); and
program code to perform vector operations on the two inputs with the ALU.

19. The non-transitory computer-readable medium of claim 18, in which the first independent subchannel of DDR memory comprises a first plurality of meta data registers and a first plurality of memory banks and the second independent subchannel of the DDR memory comprises a second plurality of meta data registers and a second plurality of memory banks.

20. The non-transitory computer-readable medium of claim 19, in which the program code comprises program code to store output of the vector operations in the first plurality of meta data registers, the first plurality of memory banks, the second plurality of meta data registers, and/or the second plurality of memory banks.
